(19) United States
(12) Patent Application Publication
(10) Pub. No.: US 2024/0322102 A1
(43) Pub. Date: Sep. 26, 2024

(54) OPTICAL DEVICE

(71) Applicant: Asahi Kasei Microdevices Corporation, Tokyo (JP)

(72) Inventors: Yoshiki SAKURAI, Tokyo (JP); Koji MATSUSHITA, Tokyo (JP)

(73) Assignee: Asahi Kasei Microdevices Corporation, Tokyo (JP)

(21) Appl. No.: 18/599,221

(22) Filed: Mar. 8, 2024

(30) Foreign Application Priority Data
Mar. 24, 2023 (JP) 2023-049048
Feb. 14, 2024 (JP) 2024-020665

(51) Int. Cl. H01L 33/62; H01L 31/02; H01L 31/0203; H01L 33/52

(52) U.S. Cl. CPC H01L 33/62; H01L 31/02005; H01L 31/0203; H01L 33/52; H01L 2933/005; H01L 2933/0066

(57) ABSTRACT

An optical device with improved device orientation identifiability is provided without increasing manufacturing cost. An optical device (100) includes an optical element (10), a first lead frame portion (21) with opening hole (23), a second lead frame portion (22), wires (40), and a sealing material (70). A light-receiving or light-emitting surface of the optical element that is disposed in the opening hole and the second lead frame portion are each exposed at least partially from a first surface. On the first surface viewed from the front, the first lead frame portion has a rotation axis extending perpendicular to the first surface that is 180° rotationally symmetrical. The second lead frame portion exposed on the first surface has a shape that is 180° rotationally asymmetric with respect to the rotation axis. The optical element and the first lead frame portion overlap at least partially in a side view.

### CROSS-REFERENCE TO RELATED APPLICATION

This application claims priority to Japanese Patent Application No. 2023-049048 (filed on Mar. 24, 2023) and Japanese Patent Application No. 2024-020665 (filed on Feb. 14, 2024), the entire contents of which are incorporated herein by reference.

### TECHNICAL FIELD

The present disclosure relates to an optical device.

### BACKGROUND

As conventional technology for optical devices, for example, the technology disclosed in Patent Literature (PTL) 1 is known. PTL 1 realizes an optical device in which a light-receiving or light-emitting surface of an optical element is exposed to the outside while the number of steps and manufacturing cost are reduced in a predetermined manufacturing process. The predetermined manufacturing process includes the step of gluing individual elements, which detect or output electromagnetic waves, to predetermined positions on adhesive tape to which a lead frame adheres. The predetermined manufacturing process also includes the step of electrically bonding between the lead frame and each element, the step of molding the lead frame and each element, and the step of removing the adhesive tape.

### CITATION LIST

### Patent Literature

PTL 1: JP 2011-103382 A

### SUMMARY

Methods of manufacturing optical devices, in which light-receiving and light-emitting surfaces of optical elements can be exposed to the outside and manufacturing cost is reduced, have been researched and developed, and further cost reduction is desired through miniaturization of the optical devices. However, the manufacturing process described in PTL 1 includes a step that may cause a lead frame to be curved. Due to the curvature of the lead frame, excessive stress may be applied to an optical element. This may cause a yield reduction due to damage, such as cracking or chipping, to the optical element and an associated increase in manufacturing cost.

In order to reduce the stress applied to the optical element during the manufacturing process, it is conceivable to design a disposition area around the optical element to be locally less curved by surrounding the optical element by the lead frame without any breaks. However, when the optical element is surrounded by the lead frame without any breaks, a lead frame occupation area inevitably increases on an exposed surface of the optical element in an optical device, and in exchange, an area of an exposed sealing material becomes smaller. The smaller area of the sealing material exposed on a surface of the optical device makes it difficult to indicate a laser mark, which is provided on a surface of the sealing material for the purpose of identifying a serial number and the orientation of the optical device, in a sufficiently visible size. If a sealing material exposed area is increased, in other words, the size of the photoreceiver is increased in order to provide a sufficiently visible laser mark, the number of photoreceiver that can be manufactured from a single lead frame is reduced and manufacturing cost increases. If the optical element is prevented from damage such as cracking or chipping by improving the design of the lead frame without increasing the manufacturing cost, it is not possible to provide a sufficiently visible laser mark. This makes it difficult to identify the orientation of the optical device, which may lead to a defect such as a malfunction due to mounting the device on a mounting board in the opposite orientation.

It would be helpful to provide an optical device with improved device orientation identifiability without increasing manufacturing cost.

(1) An optical device according to an embodiment of the present disclosure includes:
an optical element configured to detect or emit light;
a first lead frame portion having one penetrating opening hole;
a second lead frame portion different from the first lead frame portion;
a wire electrically bonding between both or one of the first and second lead frame portions and the optical element; and
a sealing material that seals the optical element, the first lead frame portion, the second lead frame portion, and the wire,
wherein
the optical element is disposed in the opening hole,
a light-receiving or light-emitting surface of the optical element and the second lead frame portion are each exposed at least partially from a first surface,
in a plan view of the first surface viewed from a front, the first lead frame portion has a rotation axis extending perpendicular to the first surface that is 180° rotationally symmetrical,
the second lead frame portion exposed on the first surface has a shape that is 180° rotationally asymmetric with respect to the rotation axis, and
the optical element and the first lead frame portion overlap at least partially in a side view.

(2) As an embodiment of the present disclosure, in (1), the optical element is a sensor configured to detect infrared radiation.

(3) As an embodiment of the present disclosure, in (1), the optical element is an LED configured to emit infrared radiation.

(4) As an embodiment of the present disclosure, in any one of (1) to (3), in the plan view, an exposed portion of the first lead frame portion surrounds an exposed portion of the optical element without any breaks.

(5) As an embodiment of the present disclosure, in any one of (1) to (4), the light-receiving or light-emitting surface of the optical element is formed on a semiconductor substrate that has been subjected to roughening processing.

(6) As an embodiment of the present disclosure, in (5), the semiconductor substrate has a thickness of 400 μm or less.

(7) As an embodiment of the present disclosure, in any one of (1) to (6), a distance from an end of the opening hole to the optical element is 70 μm or more.

(8) As an embodiment of the present disclosure, in any one of (1) to (7), a distance from an end of the opening hole to the optical element is 200 μm or less.

(9) As an embodiment of the present disclosure, in any one of (1) to (8), in the second lead frame portion, an area in which a non-etched area of a front surface overlaps a non-etched area of a back surface has a width of 100 μm or less in at least one place.

(10) As an embodiment of the present disclosure, in any one of (1) to (9),
the first surface has an asymmetric area, in which no second lead frame portion is present and the sealing material is exposed, to form an asymmetric shape, and
a third lead frame portion is exposed on a second surface opposite the first surface, in an area that overlaps the asymmetric area.

(11) As an embodiment of the present disclosure, in (10), the second lead frame portion and the third lead frame portion are connected inside the optical device.

(12) As an embodiment of the present disclosure, in any one of (1) to (11), part of the second lead frame portion is not directly connected to a side surface on the first surface. Therefore, the optical device has a minimum distance d between the side surface and the second lead frame portion that is not connected to the side surface.

(13) As an embodiment of the present disclosure, in (12), the minimum distance d is 0.1 mm or more.

(14) As an embodiment of the present disclosure, in (12), the minimum distance d is 1.0 mm or less.

(15) As an embodiment of the present disclosure, in (12), the minimum distance d is 1/30 or more the length D of a side of the optical device in a direction parallel to the minimum distance d in the plan view.

(16) As an embodiment of the present disclosure, in (12), the minimum distance d is ⅓ or less the length D of a side of the optical device in a direction parallel to the minimum distance d in the plan view.

According to the present disclosure, it is possible to provide an optical device with improved device orientation identifiability without increasing manufacturing cost.

### BRIEF DESCRIPTION OF THE DRAWINGS

In the accompanying drawings:

FIG. 1A is a diagram illustrating an example of a configuration of an optical device according to an embodiment of the present disclosure;

FIG. 1B is a diagram illustrating an example of the configuration of the optical device according to the embodiment of the present disclosure;

FIG. 2 is a cross-sectional view of an example of a configuration of an optical element;

FIG. 3A is a plan view illustrating an example of a configuration of a lead frame;

FIG. 3B is a plan view illustrating the example of the configuration of the lead frame;

FIG. 4A is a plan view illustrating an example of a configuration of a second lead frame portion;

FIG. 4B is a plan view illustrating another example of the configuration of the second lead frame portion;

FIG. 4C is a plan view illustrating another example of the configuration of the second lead frame portion;

FIG. 4D is a plan view illustrating another example of the configuration of the second lead frame portion;

FIG. 4E is a plan view illustrating yet another example of the configuration of the second lead frame portion;

FIG. 4F is a plan view illustrating an example of a configuration of a second lead frame portion according to Comparative Example;

FIG. 4G is a plan view illustrating another example of the configuration of the second lead frame portion according to Comparative Example;

FIG. 5 is a diagram illustrating the results of analysis of stress simulation;

FIG. 6A is a process diagram illustrating a method of manufacturing the optical device according to the embodiment of the present disclosure;

FIG. 6B is a process diagram illustrating the method of manufacturing the optical device according to the embodiment of the present disclosure;

FIG. 6C is a process diagram illustrating the method of manufacturing the optical device according to the embodiment of the present disclosure;

FIG. 6D is a process diagram illustrating the method of manufacturing the optical device according to the embodiment of the present disclosure;

FIG. 6E is a process diagram illustrating the method of manufacturing the optical device according to the embodiment of the present disclosure;

FIG. 6F is a process diagram illustrating the method of manufacturing the optical device according to the embodiment of the present disclosure;

FIG. 6G is a process diagram illustrating the method of manufacturing the optical device according to the embodiment of the present disclosure; and

FIG. 7 is a cross-sectional view of an optical device according to another embodiment.

### DETAILED DESCRIPTION

An optical device according to an embodiment of the present disclosure will be described below with reference to the drawings. In the drawings, the same or corresponding portions are denoted by the same reference numerals. In the description of the embodiment, descriptions of the same or corresponding portions are omitted or simplified as appropriate. The optical device includes an optical element that detects or emits light. The optical device can be a light-receiving device in which the optical element is a sensor that detects infrared radiation. The optical device can also be a light-emitting device in which the optical element is an LED that emits infrared radiation. For example, the light-emitting device can be realized with the same structure as the light-receiving device, so the light-receiving device and the light-emitting device are collectively described below as an optical device.

### [Optical Device]

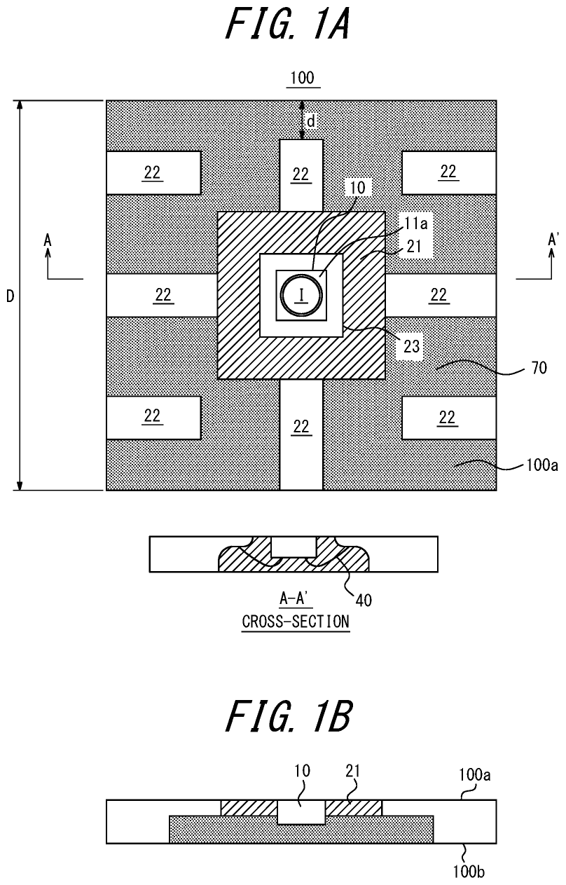

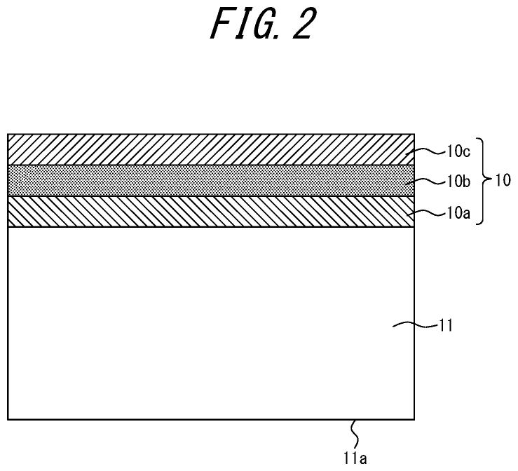

FIGS. 1A and 1B are diagrams illustrating examples of a configuration of an optical device 100 according to an embodiment of the present disclosure. The optical device 100 according to this embodiment includes an optical element 10, a first lead frame portion 21 having one penetrating opening hole, and a second lead frame portion 22 that is different from the first lead frame portion 21. In other words, a lead frame of the optical device 100 is configured with the first lead frame portion 21 and the second lead frame portion 22. The optical device 100 also includes wires 40 that electrically bond between both or one of the first and second lead frame portions 21 and 22 and the optical element 10. The optical device 100 also includes a sealing material 70 that seals the optical element 10, the first lead frame portion 21, the second lead frame portion 22, and the wires 40. The optical element 10 is formed on a semiconductor substrate 11 (see FIG. 2) and has the function of outputting a signal in response to the amount of light applied or emitting light in response to a current applied. The optical element 10 is disposed in an opening hole 23 that penetrates through the first lead frame portion 21. A light-receiving or light-emitting surface 11a of the optical element 10 and the second lead frame portion 22 are each exposed at least partially from a first surface 100a of the optical device 100. In a plan view of the first surface 100a of the optical device 100 viewed from the front, the first lead frame portion 21 has a rotation axis I extending perpendicular to the first surface that is 180° rotationally symmetrical. The second lead frame portion 22 exposed on the first surface 100a of the optical device 100 has a shape that is 180° rotationally asymmetric with respect to the rotation axis I. As illustrated in FIG. 1B, the optical element 10 and the first lead frame portion 21 overlap at least partially in a side view of the optical device 100. The side view refers to viewing the cross-section of the optical device 100 illustrated in FIG. 1A along the A-A′ line so that the first surface 100a faces up and a second surface 100b faces down.

The optical device 100 is mounted on a printed circuit board or the like with a side opposite the light-receiving or light-emitting surface 11a of the optical element 10, that is, the second surface 100b illustrated in FIG. 1B as a mounting surface. When the optical device 100 is mounted on the printed circuit board or the like, a laser mark is provided on the first surface 100a of the optical device 100 to identify the orientation of the optical device 100. In order to provide the laser mark with sufficient visibility, the laser mark of a visually recognizable size is required on a portion other than the lead frame, in which the visibility of the laser mark is significantly reduced, i.e., an exposed area of the sealing material 70. Therefore, in order to provide the laser mark with sufficient visibility, it is necessary to secure the sufficient exposed area of the sealing material 70 to provide the laser mark on the first surface 100a of the optical device 100. For example, it is necessary to reduce a lead frame occupation area on the first surface 100a of the optical device 100, or upsize the optical device 100 by widening the first surface 100a of the optical device 100.

At this time, removing the entirety or part of the first lead frame portion 21 increases the risk of damage to the optical device 10 during a manufacturing process. Also, upsizing the optical device 100 to widen the area of the sealing material 70 increases manufacturing cost. Therefore, in order to realize the optical device 100 with easy orientation identification without increasing the manufacturing cost, a method for orientation identification other than the laser mark is required.

### [Optical Element]

FIG. 2 is a cross-sectional view of an example of a configuration of the optical element 10. The optical element 10 is composed of a first compound semiconductor layer 10a, an active layer 10b, and a second compound semiconductor layer 10c, which are stacked in this order. The first compound semiconductor layer 10a is formed on one main plane of the semiconductor substrate 11 and has a first conductivity type. The active layer 10b is formed on the first compound semiconductor layer 10a and is made of a compound semiconductor material. The second compound semiconductor layer 10c is formed on the active layer 10b and has a second conductivity type. Here, “the first compound semiconductor layer 10a, the active layer 10b, and the second compound semiconductor layer 10c are stacked in this order” means that the stacking order is the first compound semiconductor layer 10a, the active layer 10b, and the second compound semiconductor layer 10c in relation to these layers. An aspect of the configuration in which “the first compound semiconductor layer 10a, the active layer 10b, and the second compound semiconductor layer 10c are stacked in this order” includes the case of inserting another layer between, for example, the first compound semiconductor layer 10a and the active layer 10b. An aspect of the configuration in which “the first compound semiconductor layer 10a, the active layer 10b, and the second compound semiconductor layer 10c are stacked in this order” includes the case of inserting another layer between the active layer 10b and the second compound semiconductor layer 10c. Here, the main plane is a plane perpendicular to a thickness direction of the semiconductor substrate 11 and is a plane with the largest area among six planes that form the semiconductor substrate 11.

The optical element 10 is not particularly limited as long as the optical element 10 includes a diode structure with a PN or PIN junction. The first and second conductive semiconductor layers have opposite conductivity types. For example, when the first conductive semiconductor layer is p-type, the second conductive semiconductor layer is n-type. For example, when the first conductive semiconductor layer is n-type, the second conductive semiconductor layer is p-type. Materials for the first and second conductive semiconductor layers include InSb, InAsSb, and AlInSb, but are not limited to these. The first and second conductive semiconductor layers may be composed of a stacked structure of multiple materials.

Examples of the semiconductor substrate 11 include a GaAs substrate, an InP substrate, an InSb substrate, and an InAs substrate, but are not limited to these and other insulating substrates are also acceptable. One example is ceramic. The GaAs substrate is preferable because of the ease of crystal growth of compound semiconductors.

The thickness of the semiconductor substrate 11 used to form the optical element 10 is preferably polished as thin as 400 μm or less, from the viewpoint of downsizing the optical device 100. However, the thinner the substrate is polished, the lower the strength of the optical element 10 becomes. Therefore, stress applied in the manufacturing process is set so that damage, such as cracking or chipping, to the optical element 10 does not occur.

In polishing the semiconductor substrate 11, a polished surface is preferably subjected to roughening processing in order to improve the light-receiving sensitivity or light-emitting intensity of the optical element 10. In other words, it is preferable that the light-receiving or light-emitting surface 11a of the optical element 10 is formed on the roughened semiconductor substrate 11. However, since the roughening processing destroys a crystal structure on the surface of the substrate and reduces the strength of the substrate, the stress applied in the manufacturing process is set so that damage, such as cracking or chipping, to the optical element 10 does not occur. Here, a “rough surface” refers to a surface state with an arithmetic mean roughness of 100 nm or more.

### [Lead Frame]

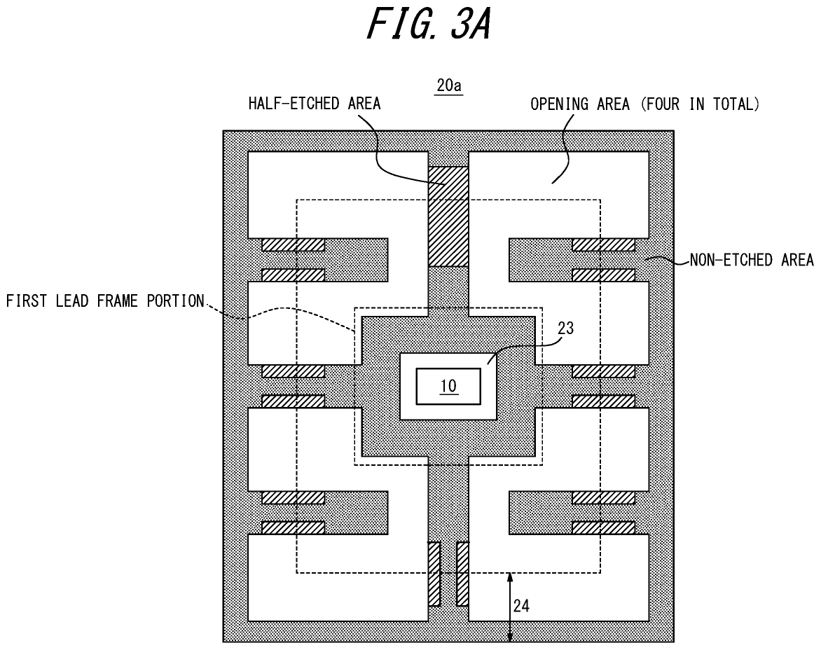

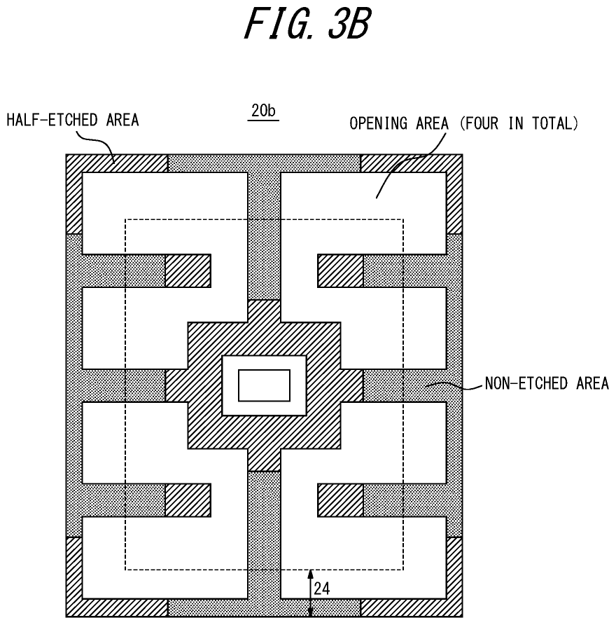

FIGS. 3A and 3B are plan views illustrating an example of a configuration of the lead frame. FIG. 3A illustrates a front surface 20a of the lead frame, and FIG. 3B illustrates a back surface 20b of the lead frame.

The lead frame illustrated in FIGS. 3A and 3B is formed, for example, by selectively etching a copper (Cu) plate from the front surface 20a and back surface 20b sides using photolithography technology, and then being subjected to plate processing. The plate processing may be, for example, nickel (Ni)-palladium (Pd)-gold (Au) or the like.

In FIG. 3A, the white areas in the lead frame indicate opening areas that penetrate between the front surface 20a and the back surface 20b. Also, the hatched areas (areas shaded with oblique lines) indicate areas that have been half-etched from the front surface 20a side. Hereafter, the areas that have been half-etched are referred to as “half-etched areas”. The gray areas indicate areas that have not been etched (i.e., non-etched areas) due to the front surface 20a being masked by photoresist or the like during etching. The area surrounded by a dotted line indicates the first lead frame portion 21 with the opening hole 23 in which the optical element 10 is disposed.

Similarly, in FIG. 3B, the white areas in the lead frame indicate opening areas. The hatched areas indicate half-etched areas that have been half-etched from the back surface 20b side. The gray areas indicate non-etched areas that have not been etched due to the back surface 20b being masked by photoresist or the like during etching. Here, an outer periphery of the lead frame illustrated in FIGS. 3A and 3B is an area (with a kerf width 24) that is to be cut by a dicing blade or the like in a dicing step described below. In the second lead frame portion 22, an area in which a non-etched area of the front surface 20a overlaps a non-etched area of the back surface 20b has a width of 100 μm or less in at least one place.

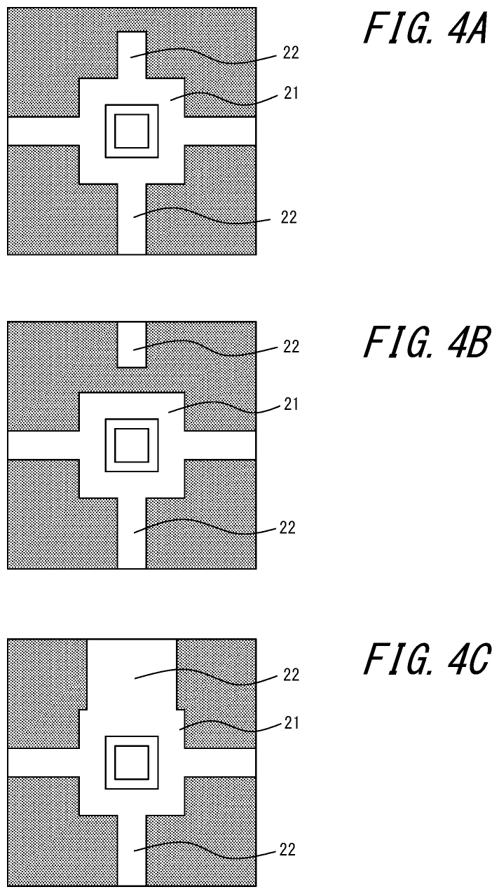

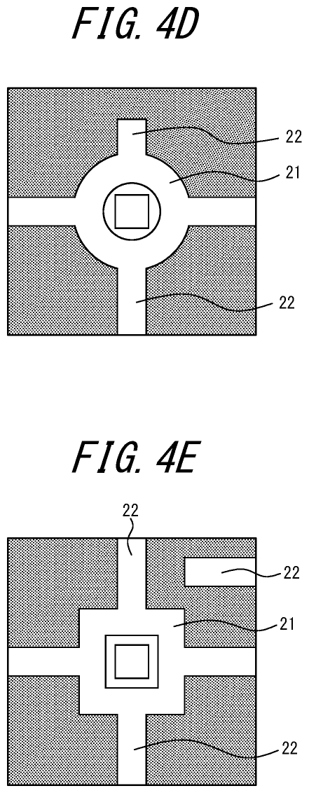

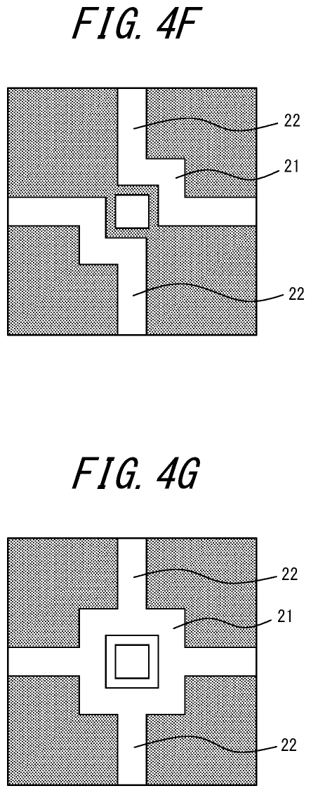

In the plan view illustrated in FIG. 3A, the shape of the opening hole 23 in the first lead frame portion 21 is preferably the same as the shape of the optical element 10, but is not particularly limited. The opening hole 23 may have a different shape, such as circular, for example, as illustrated in FIG. 4D.

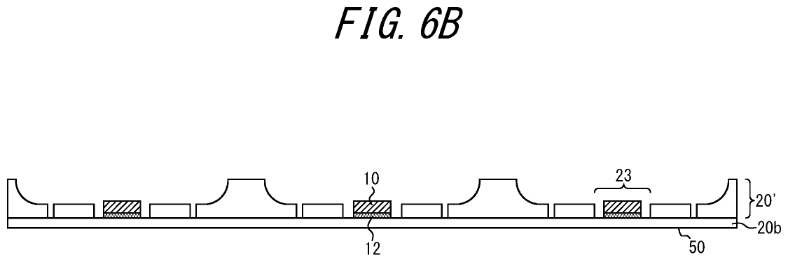

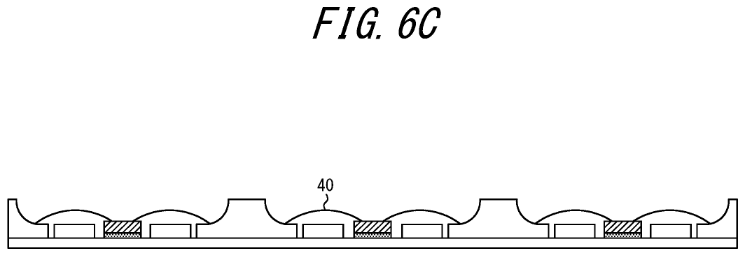

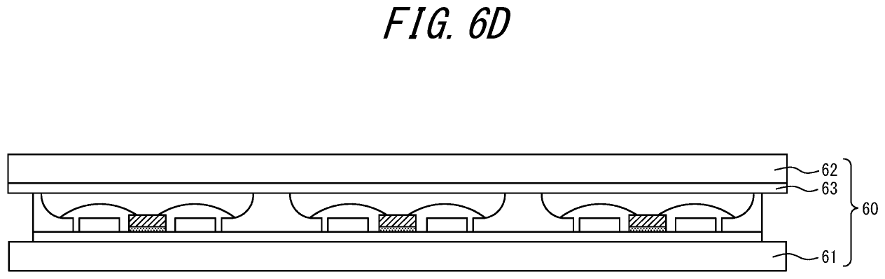

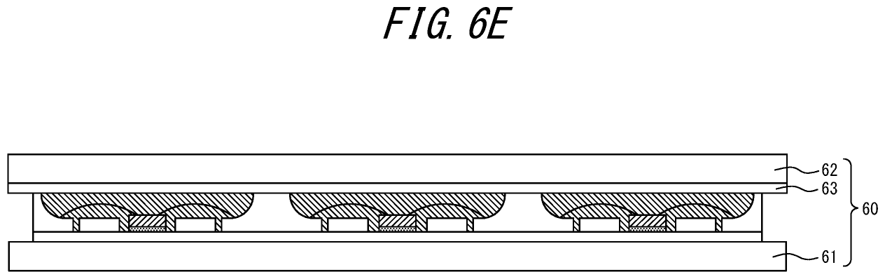

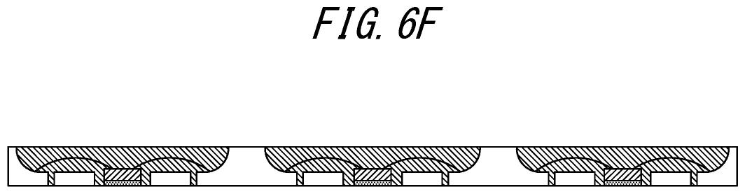

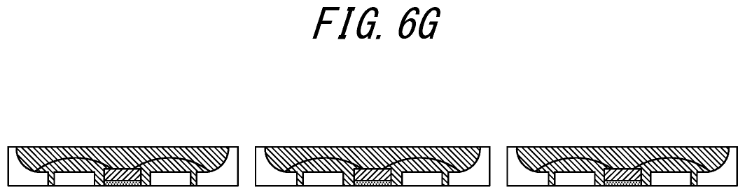

The optical element 10 is disposed in the opening area of the lead frame. Conventionally, stress applied to the optical element 10 in a wire bonding step illustrated in FIG. 6C and a resin sealing illustrated in FIG. 6E sometimes causes cracking or chipping of the optical element 10. Also, conventionally, destruction of the optical element 10 is likely to occur in the step of peeling off adhesive tape 50 from the back surface side of a lead frame 20′ illustrated in FIG. 6F.

In the present disclosure, the lead frame includes the first lead frame portion 21 that surrounds the optical element 10 without any breaks in order to reduce stress applied to the optical element 10 in the manufacturing process, and is designed to prevent local curvature around the optical element 10 in the manufacturing process. It is also preferable that the first lead frame portion 21 is present at a height at least partially overlapping the optical element 10, from the viewpoint of effectively reducing the stress applied to the optical element 10. Furthermore, it is further preferable that an exposed portion of the first lead frame portion 21 surrounds, without any breaks, the light-receiving or light-emitting surface 11a (exposed portion) of the optical element 10 on the first surface 100a of the optical device 100 as illustrated in FIG. 1B.

A defect of the provision of the first lead frame portion 21 with the above features is that the area of the sealing material 70 occupying the first surface 100a of the optical device 100 is reduced. When the sealing material 70 of a sufficient size cannot be provided on the opposite side (i.e., first surface 100a) of the second surface 100b, which is a printed circuit board mounting side, a mark for a serial number and orientation identification must be laser marked on the lead frame. It is known that laser marks on the lead frame are significantly less visible than laser marks on the sealing material 70. It is also clear that visibility deteriorates when the size of a laser mark is reduced to match the area of the sealing material 70 occupying the first surface 100a.

Conventionally, from the viewpoint of equalizing stress applied to the optical device 10 in the manufacturing process, the lead frame preferably has a shape that is 180° rotationally symmetric with respect to the rotation axis I. In this case, the orientation of the optical device 100 is identified by a laser mark provided on an exposed surface of the sealing material 70. However, when the laser mark is difficult to provide, the orientation identifiability of the optical device 100 can be improved by providing a lead frame with a rotationally asymmetric portion, after ensuring that the stress applied to the optical element 10 is as uniform as possible. In other words, the lead frame may have an asymmetric area in which an exposed portion of the lead frame overlaps a non-exposed portion of the lead frame when the lead frame is rotated 180°.

In the present disclosure, in the plan view of the first surface 100a of the optical device 100 viewed from the front. The second lead frame portion 22 has a rotation axis I extending perpendicular to the first surface that is 180° rotationally asymmetric.

As a measure to provide a laser mark with sufficient visibility on the first surface 100a, it is conceivable to upsize the optical device 100 sufficiently relative to the optical element 10, but this in turn increases the manufacturing cost due to the upsizing of the optical device 100. Therefore, in order to keep the optical device 100 to a minimum size relative to the optical element 10, to have the first lead frame portion 21, and to ensure the orientation identifiability of the light-receiving or light-emitting element, it is most effective to provide the second lead frame portion 22.

As a specific example, when the light-receiving or light-emitting surface 11a of the optical element 10 is 0.1 mm² or more and the area of the first surface 100a of the optical device 100 is 25 mm² or less, providing the second lead frame portion 22 is more effective than orientation identifiability by a laser mark. Furthermore, when the area of the first surface 100a of the optical device 100 is 9 mm² or less, providing the second lead frame portion 22 is more effective.

As methods of realizing the second lead frame portion 22, for example, methods illustrated in FIGS. 4A to 4E are suggested, but are not particularly limited. Specifically, arms extending from the first lead frame portion 21 are provided, and part of the arms is removed, changed in shape, or the like.

In Comparative Example 1 illustrated in FIG. 4F, the first lead frame portion 21 surrounding the optical element 10 has cuts, and therefore the lead frame around the optical element 10 is easily curved during the manufacturing process. This increases the risk of damage, such as cracking or chipping, to the optical element 10 during the manufacturing process.

In Comparative Example 2 illustrated in FIG. 4G, the second lead frame sections 22 are 180° rotationally symmetric with respect to the rotation axis I. In this case, even if the light-receiving or light-emitting element has been rotated 180°, the rotation cannot be noticed, and the risk of mounting the optical device 100 in the opposite orientation on a board is increased.

When the penetrating opening hole 23 provided in the first lead frame portion 21 is significantly larger in size than the optical element 10, the effect of the first lead frame portion 21 in relieving stress applied to the optical element 10 is reduced. Therefore, a distance from an end of the penetrating opening hole 23 provided in the first lead frame portion 21 to the optical element 10 is preferably 200 μm or less.

When the penetrating opening hole 23 provided in the first lead frame portion 21 is not large in size enough to the optical element 10, the optical element 10 may contact the end of the opening hole 23 in the step of disposing the optical element 10 in the opening hole 23, which may make manufacturing difficult. Therefore, the distance from the end of the penetrating opening hole 23 provided in the first lead frame portion 21 to the optical element 10 is preferably 70 μm or more. The distance from the end of the penetrating opening hole 23 provided in the first lead frame portion 21 to the optical element 10 is more preferably 100 μm or more.

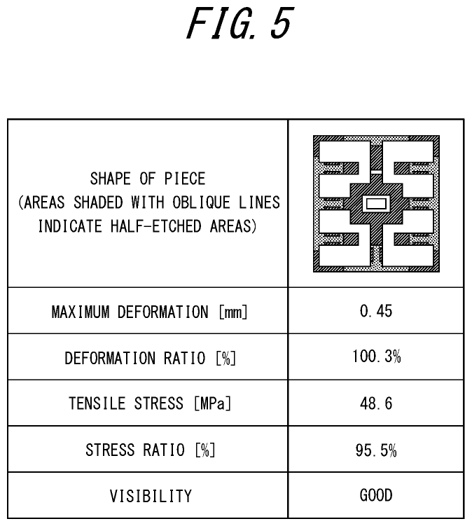

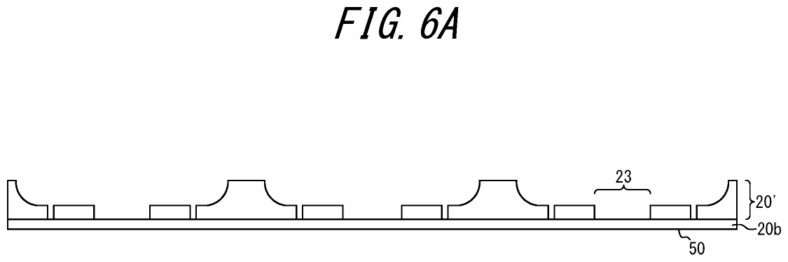

FIG. 5 illustrates the results of analysis of stress simulation. The stress simulation analyzed how much the design of the second lead frame portion 22 affects the risk of damage to the optical element 10 during the manufacturing process. This analysis is based on a structure in which the second lead frame portion 22 has arms extending from the top, bottom, left, and right of the first lead frame portion 21 toward an outer circumferential direction. By changing a half-etched area of one of the arms, the simulation was performed to see how stress applied to the optical element 10 changes when the lead frame is curved.

The results of the analysis indicate that the design illustrated in FIG. 5 with wide half-etched areas can minimize the stress applied to the optical element 10. According to this analysis, the second lead frame portion 22 is preferably designed to have portions with a minimum non-etched area at least partially, in order to absorb stress caused by the curvature of the lead frame before dicing. The minimum non-etched area is defined from minimum processing dimensional accuracy in lead frame manufacturing, and has a width of 100 μm, for example.

### [Sealing Material]

The sealing material 70 is not particularly limited as long as the the sealing material 70 can seal the optical element 10, the first lead frame portion 21, the second lead frame portion 22, and the wires 40. For example, a mold resin described below is applicable.

Next, a method of manufacturing the optical device 100 using the optical element 10, the lead frame, and the sealing material 70 will be described.

FIGS. 6A to 6G are process diagrams illustrating the method of manufacturing the optical device 100 according to the embodiment. Here, each cross-section in these process diagrams corresponds to, for example, a cross-section along the A-A′ line of the optical device 100 illustrated in FIG. 1A.

As illustrated in FIG. 6A, a lead frame 20′ is first prepared. Here, the lead frame 20′ in which the lead frame illustrated in FIGS. 3A and 3B is used as one unit pattern and multiple unit patterns are arranged continuously in vertical and horizontal directions in a plan view is prepared.

Next, the adhesive tape 50 adheres to a back surface 20b of the lead frame 20′. Due to the adhesive tape 50 adhering to the back surface 20b of the lead frame 20′, an adhesive layer of the adhesive tape 50 is exposed on bottom surfaces of opening holes 23. Here, as the adhesive tape 50, resin tape having heat resistance, as well as adhesiveness, is used. With respect to the adhesiveness, the thinner glue thickness of the adhesive layer, the better. With respect to the heat resistance, the tape is required to withstand temperatures of approximately 150° C. to 200° C. Polyimide tape, for example, can be used as such adhesive tape 50. The polyimide tape has heat resistance to withstand a temperature of approximately 280° C. The polyimide tape with such high heat resistance can withstand a high temperature applied during subsequent molding and wire bonding.

In addition to the polyimide tape, the following tape can be used as the adhesive tape 50. The adhesive tape 50 may be polyester tape. The polyester tape has a heat resistance temperature of approximately 130° C. and can reach approximately 200° C. depending on the conditions of use. The adhesive tape 50 may be Teflon® (Teflon is a registered trademark in Japan, other countries, or both) tape. The Teflon® tape has a heat resistance temperature of approximately 180° C. The adhesive tape 50 may be polyphenylene sulfide (PPS). The PPS has a heat resistance temperature of approximately 160° C. The adhesive tape 50 may be glass cloth. The glass cloth has a heat resistance temperature of approximately 200° C. The adhesive tape 50 may be Nomex® (Nomex is a registered trademark in Japan, other countries, or both) paper. The Nomex® paper has heat resistance temperatures of approximately 150° C. to 200° C. The adhesive tape 50 may be aramid or crepe paper.

Next, as illustrated in FIG. 6B, the optical element 10 is glued in each opening hole 23 of the lead frame 20′. This gluing is performed with a back surface of the semiconductor substrate 11 of the optical element 10 as a glued surface. A protective film 12 is formed on the back surface of the semiconductor substrate 11 before the semiconductor substrate 11 is diced individually. Photoresist is used as the protective film 12 on the back surface of the semiconductor substrate 11.

Next, as illustrated in FIG. 6C, each optical element 10 and the lead frame 20′ are electrically bonded. Here, as illustrated in FIG. 1A, pad electrodes of each optical element 10 and bonding terminals of the lead frame 20′ are bonded with the wires 40 made of Au or the like.

Next, the lead frame 20′ in the state illustrated in FIG. 6C is placed in a mold 60, and the sealing material 70 is formed on the top surface side of the lead frame 20′. Specifically, as illustrated in FIG. 6D, the mold 60, which includes a lower mold 61 and an upper mold 62, and a sheet 63 are prepared. The sheet 63 is disposed so as to cover the entire bottom surface of the upper mold 62 (a surface facing the lower mold 61). The sheet 63 is made of Teflon® for example.

Next, the lead frame 20′ in the state illustrated in FIG. 6C is placed in the mold 60. Specifically, the lead frame 20′ is placed on the lower mold 61 with the metal wires 40 side facing up. The upper mold 62 is placed at a predetermined distance above the wires 40. The sheet 63 is adsorbed on the bottom surface of the upper mold 62. FIG. 6D illustrates this state.

Next, after a mold resin is poured into the space between the upper mold 62 and the lower mold 61 in the state illustrated in FIG. 6D, the upper mold 62 is lowered to apply a compressive force to the mold resin so that the distance between a bottom surface of the sheet 63 and a top surface of the lower mold 61 is adjusted to a set value. Thereafter, the mold resin is cooled. This forms the sealing material 70. FIG. 6E illustrates this state.

Here, for example, an epoxy resin can be used as the mold resin. In this resin sealing step, the sheet 63 and non-etched areas on the front surface 20a side of the lead frame 20′ are in contact without any gaps. In addition, the mold resin is supplied from a side of the space formed by the overlapping of the mold 60 while the lower mold 61, non-etched areas on the back surface 20b side of the lead frame 20′, and the adhesive tape 50 adhering to the optical element 10 are in contact without any gaps. Therefore, after the resin sealing, the non-etched areas of the lead frame 20′ are exposed from the mold resin.

Next, as illustrated in FIG. 6F, the adhesive tape 50 is removed from the back surface 20b side of the lead frame 20′. After the adhesive tape 50 is removed, post-curing and wet blasting are performed. Thereafter, as illustrated in FIG. 6G, the mold resin and the lead frame 20′ are diced by a dicing machine with the kerf width 24. The mold resin and the lead frame 20′ are then separated into individual products and packaged to complete the individual optical devices 100 illustrated in FIGS. 1A and 1B.

In the above manufacturing method, the stress applied to the optical element 10 in each step is relieved by disposing the optical element 10 in the opening hole 23 provided in the first lead frame portion 21. Furthermore, the present disclosure eliminates the reduced orientation identifiability of the light-receiving and light-emitting element, which occurs as a defect of the provision of the first lead frame portion 21, by adopting the structure with the second lead frame portion 22.

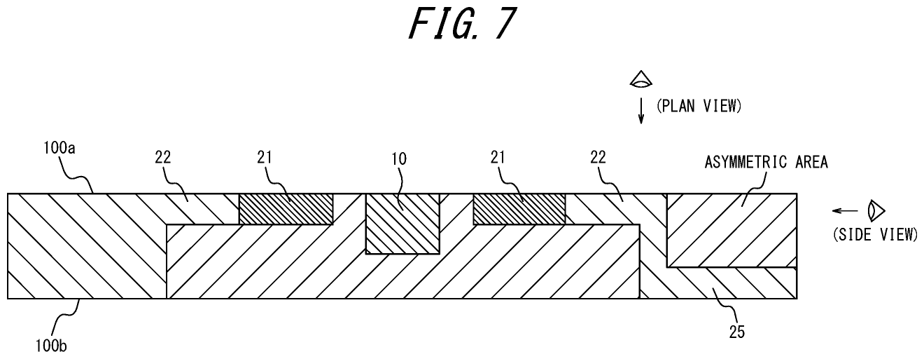

Here, the optical device 100 can be configured with a cross-section as illustrated in FIG. 7. In FIG. 7, the relationship with a third lead frame portion 25 is defined as follows, in contrast to the configuration of FIG. 1A. The optical device 100 according to this embodiment includes an optical element 10, a first lead frame portion 21 having one penetrating opening hole, a second lead frame portion 22 different from the first lead frame portion 21, and a third lead frame portion 25. In other words, a lead frame of the optical device 100 is constituted of the first lead frame portion 21, the second lead frame portion 22, and the third lead frame portion 25. The first lead frame portion 21, the second lead frame portion 22, and the third lead frame portion 25 may be made of the same material or different materials, and may be formed integrally or separately (and then connected). The optical device 100 includes wires 40 that electrically bond between at least one of the first lead frame portion 21, the second lead frame portion 22, or the third lead frame portion 25 and the optical element 10. The optical device 100 also includes a sealing material 70 that seals the optical element 10, the first lead frame portion 21, the second lead frame portion 22, the third lead frame portion 25, and the wires. The optical element 10 is formed on a semiconductor substrate 11 (see FIG. 2) and has the function of outputting a signal in response to the amount of light applied or emitting light in response to a current applied. The optical element 10 is disposed in an opening hole 23 that penetrates through the first lead frame portion 21. A light-receiving or light-emitting surface 11a of the optical element 10 and the second lead frame portion 22 are each exposed at least partially from a first surface 100a of the optical device 100. In a plan view of the first surface 100a of the optical device 100 viewed from the front, the first lead frame portion 21 has a rotation axis I extending perpendicular to the first surface 100a that is 180° rotationally symmetrical. The second lead frame portion 22 exposed on the first surface 100a of the optical device 100 has a shape that is 180° rotationally asymmetric about the rotation axis I. The first surface 100a of the optical device 100 has an asymmetric area, in which no second lead frame portion 22 is present and the sealing material 70 is exposed, to form an asymmetric shape. The third lead frame portion 25 is exposed on a second surface 100b, which is opposite the first surface 100a, in an area that overlaps the asymmetric area. As illustrated in FIG. 1B, the optical element 10 and the first lead frame portion 21 overlap at least partially in a side view of the optical device 100.

As illustrated in FIG. 7 in the cross-sectional view of the optical device 100, the second lead frame portion 22 and the third lead frame portion 25 are electrically connected inside the optical device 100. The second lead frame portion 22 has the asymmetric area on the first surface 100a of the optical device 100. The third lead frame portion 25 is a lead frame that is exposed on the second surface 100b in an area that overlaps the asymmetric area of the second lead frame portion 22 on the first surface 100a.

As illustrated in FIGS. 4A, 4B, and 4D, the second lead frame portion 22 may have, on the first surface 100a of the optical device 100, the asymmetric area by removing part of an arm extending from the first lead frame portion 21. Therefore, part of the second lead frame portion 22 may not be directly connected to a side surface of the optical device 100 on the first surface 100a. At this time, the optical device 100 has a minimum distance d between the second lead frame portion 22 and the side surface of the optical device 100.

The minimum distance d is preferably 0.1 mm or more. To make the minimum distance d equal to or larger than a print size of a laser mark, the minimum distance d is more preferably 0.2 mm or more. To improve visibility, the minimum distance d is even more preferably 0.4 mm or more.

The minimum distance d is preferably 1.0 mm or less. To improve the strength of optical devices 100, the minimum distance d is more preferably 0.9 mm or less. The minimum distance d is even more preferably 0.6 mm or less.

When a length D represents the length of one side of the optical device 100 in a direction parallel to the minimum distance d, in a plan view of the first surface 100a of the optical device 100 viewed from the front, the minimum distance d is preferably 1/30 or more the length D of one side of the optical device 100. The minimum distance d is more preferably 1/15 or more the length D of one side of the optical device 100. The minimum distance d is even more preferably ¼ or more the length D of one side of the optical device 100.

The minimum distance d is preferably ⅓ or less the length D of one side of the optical device 100.

As described above, the optical devices 100 according to these embodiments employ the lead frame structure with the first lead frame portion 21 and the second lead frame portion 22. This can improve device orientation identifiability without increasing manufacturing cost. This can also prevent damage, such as cracking or chipping, to the optical device 10, which may occur with conventional technology.

Although the embodiments of the present disclosure have been described based on the drawings and examples, it should be noted that a person skilled in the art can easily make various variations or modifications based on the present disclosure. Accordingly, it should be noted that these variations or modifications are included in the scope of the present disclosure.

1. An optical device comprising:
an optical element configured to detect or emit light;
a first lead frame portion having one penetrating opening hole;
a second lead frame portion different from the first lead frame portion;
a wire electrically bonding between both or one of the first and second lead frame portions and the optical element; and
a sealing material that seals the optical element, the first lead frame portion, the second lead frame portion, and the wire,
wherein
the optical element is disposed in the opening hole,
a light-receiving or light-emitting surface of the optical element and the second lead frame portion are each exposed at least partially from a first surface,
in a plan view of the first surface viewed from a front, the first lead frame portion has a rotation axis extending perpendicular to the first surface that is 180° rotationally symmetrical;
the second lead frame portion exposed on the first surface has a shape that is 180° rotationally asymmetric with respect to the rotation axis, and
the optical element and the first lead frame portion overlap at least partially in a side view.

2. The optical device according to claim 1, wherein the optical element is a sensor configured to detect infrared radiation.

3. The optical device according to claim 1, wherein the optical element is an LED configured to emit infrared radiation.

4. The optical device according to claim 1, wherein in the plan view, an exposed portion of the first lead frame portion surrounds an exposed portion of the optical element without any breaks.

5. The optical device according to claim 1, wherein the light-receiving or light-emitting surface of the optical element is formed on a semiconductor substrate that has been subjected to roughening processing.

6. The optical device according to claim 5, wherein the semiconductor substrate has a thickness of 400 μm or less.

7. The optical device according to claim 1, wherein a distance from an end of the opening hole to the optical element is 70 μm or more.

8. The optical device according to claim 1, wherein a distance from an end of the opening hole to the optical element is 200 μm or less.

9. The optical device according to claim 1, wherein in the second lead frame portion, an area in which a non-etched area of a front surface overlaps a non-etched area of a back surface has a width of 100 μm or less in at least one place.

10. The optical device according to claim 1, wherein
the first surface has an asymmetric area, in which no second lead frame portion is present and the sealing material is exposed, to form an asymmetric shape, and
a third lead frame portion is exposed on a second surface opposite the first surface, in an area that overlaps the asymmetric area.

11. The optical device according to claim 10, wherein the second lead frame portion and the third lead frame portion are connected inside the optical device.

12. The optical device according to claim 1, wherein part of the second lead frame portion is not directly connected to the side on the first surface, and thus has a minimum distance d to the side.

13. The optical device according to claim 12, wherein the minimum distance d is 0.1 mm or more.

14. The optical device according to claim 12, wherein the minimum distance d is 1.0 mm or less.

15. The optical device according to claim 12, wherein the minimum distance d is 1/30 or more the length D of a side of the optical device in a direction parallel to the minimum distance d in the plan view.

16. The optical device according to claim 12, wherein the minimum distance d is ⅓ or less the length D of a side of the optical device in a direction parallel to the minimum distance d in the plan view.
